(19) United States
(12) Patent Application Publication
(10) Pub. No.: US 2013/0169336 A1
(43) Pub. Date: Jul. 4, 2013

(54) ELECTRONIC DEVICE

(71) Applicant: Nikon Corporation, Tokyo (JP)

(72) Inventor: Koji OZAKI, Yokohama-shi (JP)

(73) Assignee: NIKON CORPORATION, Tokyo (JP)

(21) Appl. No.: 13/682,360

(22) Filed: Nov. 20, 2012

Related U.S. Application Data
(63) Continuation of application No. PCT/JP2011/006471, filed on Nov. 21, 2011.
(60) Provisional application No. 61/562,186, filed on Nov. 21, 2011.

(30) Foreign Application Priority Data
Nov. 26, 2010 (JP) 2010-264110

(51) Int. Cl. H03K 5/1252

(52) U.S. Cl. CPC H03K 5/1252
USPC 327/261; 327/295

(57) ABSTRACT

When operational clocks are output to a plurality of connecting sections, magnetic waves caused by the rising and falling of each clock have a large effect on the surrounding area. Therefore, provided is an electronic device comprising a plurality of connecting sections that are respectively connected to a plurality of external devices having the same frequencies for operational clocks used to communicate signals; and a clock output section that outputs, respectively to the connecting sections, operational clocks that are phase-shifted relative to each other. The clock output section outputs operational clocks with inverse phases to two of the connecting sections.

### BACKGROUND

1. Technical Field

The present invention relates to an electronic device.

2. Related Art

An electronic device is known that is connected to a plurality of external devices via a plurality of connecting sections, as shown in Japanese Patent Application Publication No. 2005-92833, for example. For such an electronic device, an operation clock with the same phase is supplied through each connecting section.

However, when the operation clock is output to the connecting sections, the electromagnetic waves from the rising and falling of each operation clock cause a large amount of noise, and this has a large impact on the surrounding region.

### SUMMARY

Therefore, it is an object of an aspect of the innovations herein to provide an electronic device, which is capable of overcoming the above drawbacks accompanying the related art. The above and other objects can be achieved by combinations described in the claims. According to a first aspect of the present invention, provided is an electronic device comprising a plurality of connecting sections that are respectively connected to a plurality of external devices having the same frequencies for operational clocks used to communicate signals; and a clock output section that outputs, respectively to the connecting sections, operational clocks that are phase-shifted relative to each other.

The summary clause does not necessarily describe all necessary features of the embodiments of the present invention. The present invention may also be a sub-combination of the features described above.

### BRIEF DESCRIPTION OF THE DRAWINGS

FIG. 1 shows an overall configuration of an image capturing apparatus.

FIG. 2 shows operational clocks input to the first connecting section and the second connecting section.

FIG. 3 shows another example of operational clocks input to the first connecting section and the second connecting section.

FIG. 4 is a flowchart describing the first half of the storage information input/output operation performed by the image capturing apparatus.

FIG. 5 is a flowchart describing the second half of the storage information input/output operation performed by the image capturing apparatus.

FIG. 6 shows operational clocks output to five connection sections.

FIG. 7 shows other operational clocks output to five connecting sections.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

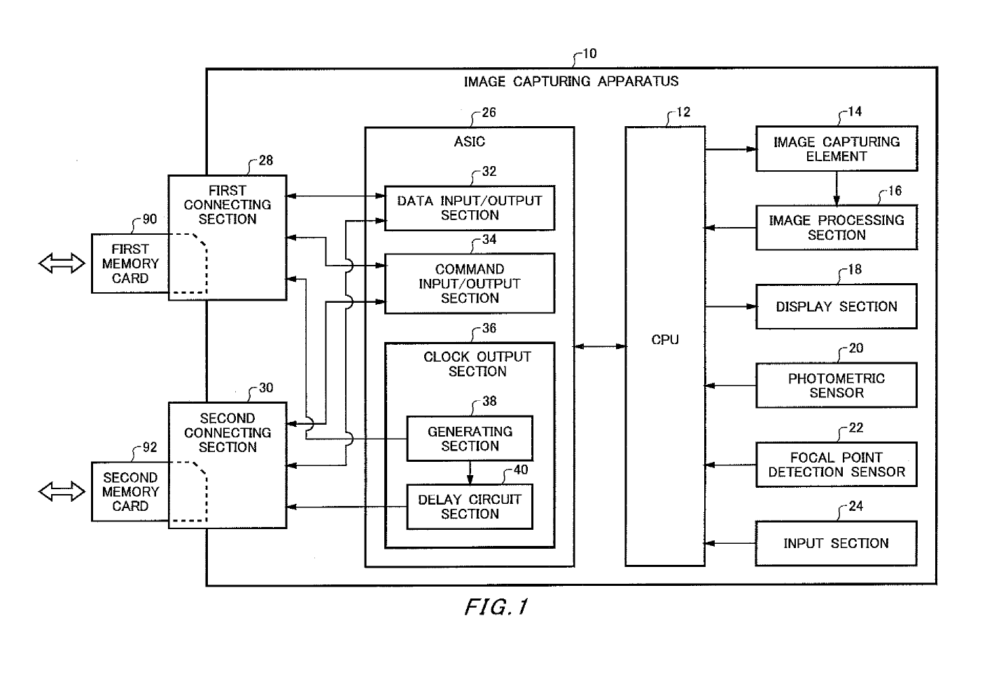

FIG. 1 shows an overall configuration of an image capturing apparatus 10. The following describes an example in which the electronic device of the present embodiment is realized as the image capturing apparatus 10. As shown in FIG. 1, the image capturing apparatus 10, which is an example of the electronic device, includes a CPU (Central Processing Unit) 12, an image capturing element 14, an image processing section 16, a display section 18, a photometric sensor 20, a focal point detection sensor 22, an input section 24, an ASIC 26, a first connecting section 28, and a second connecting section 30.

The CPU 12 performs overall control of the image capturing apparatus 10. The CPU 12 is connected to the image capturing element 14, the image processing section 16, the display section 18, the photometric sensor 20, the focal point detection sensor 22, the input section 24, and the ASIC 26 in a manner enabling the output of signals thereto and the input of signals therefrom.

The image capturing element 14 is formed by two-dimensionally arranging photoelectric converting elements, such as a CCD (Charge-Coupled Device) or CMOS (Complementary Metal-Oxide Semiconductor). The image capturing element 14 outputs to the image processing section 16 an image signal generated by photoelectrically converting a subject image.

The image processing section 16 performs analog/digital conversion on the image signal input from the image capturing element 14, converts the resulting digital signal into image data, and outputs the image data to the CPU 12.

The display section 18 is formed by a liquid crystal display, for example. The display section 18 displays the subject image and information such as setting information, based on the image data input from the CPU 12.

The photometric sensor 20 is arranged in the optical path of the subject image. The photometric sensor 20 receives a portion of the light of the subject image incident thereto through a lens unit. The photometric sensor 20 detects the subject brightness from the received light of the subject image, and outputs the subject brightness to the CPU 12. The CPU 12 calculates the diaphragm aperture, shutter speed, and sensitivity of the image capturing element 14, for example, and issues instructions to each component.

The focal point detection sensor 22 detects the defocus amount from the subject image formed by the optical system of the lens unit, and causes the lens unit to focus. At this stage, the focal point detection sensor 22 also acquires information relating to the distance from the image capturing element 14 to the subject.

The first connecting section 28 and the second connecting section 30 are respectively connected to a first memory card 90 and a second memory card 92. The first memory card 90 connected to the first connecting section 28 and the second memory card 92 connected to the second connecting section 30 receive signals according to operational clocks with the same frequency. The first memory card 90 and the second memory card 92 may be the same type of memory card, or may be different types of memory cards that operate according to operational clocks with the same frequency.

The input section 24 receives as input a manipulation performed by the user through a release button, dial, cross-key, or press button, for example, and holds the input instructions, setting values, and the like. The CPU 12 references the input section 24 to determine the operating conditions.

The ASIC 26 stores storage information, which includes image information and the like input by the CPU 12, in the first memory card 90 or the second memory card 92, which are examples of external devices, and acquires the storage information from these memory cards. An SD memory card, micro-SD card, or mini-SD card can be used as the memory cards 90 and 92. Furthermore, a memory stick, memory stick duo, memory stick micro, compact flash (registered trademark), multimedia card, xD picture card, smart media, or Secure MMC can be used as the memory cards 90 and 92. The ASIC 26 includes a data input/output section 32, a command input/output section 34, and a clock output section 36.

The data input/output section 32 outputs to the first connecting section 28 or the second connecting section 30 the storage information input by the CPU 12, and stores this information in the memory cards 90 and 92. The data input/output section 32 acquires the storage information stored in the memory cards 90 and 92 according to instructions from the CPU 12.

The command input/output section 34 outputs to the first connecting section 28 and the second connecting section 30 a command for storing the storage information input from the data input/output section 32, thereby storing the storage information in the memory cards 90 and 92. The command input/output section 34 outputs to the first connecting section 28 and the second connecting section 30 a command for acquiring the storage information stored in the memory cards 90 and 92, thereby acquiring the storage information stored in the memory cards 90 and 92. When the memory cards 90 and 92 are connected to the first connecting section 28 and the second connecting section 30, the command input/output section 34 performs an initial setting for the memory cards 90 and 92. One example of the initial setting is acquiring information concerning the storage capacity, available space, storage rate for storing the storage information, and acquisition rate for acquiring the storage information of the memory cards 90 and 92.

The clock output section 36 outputs a first operational clock CLK1 to the first connecting section 28 and outputs a second operational clock 2, whose phase is shifted relative to that of the first operational clock CLK1, to the second connecting section 30. The clock output section 36 includes a generating section 38 and a delay circuitry section 40. The generating section 38 generates the first operational clock and outputs the first operational clock CLK1 directly to the first connecting section 28. The generating section 38 outputs to the delay circuitry section 40 an operational clock whose phase is the same as that of the first operational clock CLK1. The delay circuitry section 40 delays the operational clock input from the generating section 38 to convert this operational clock into the second operational clock CLK2, and outputs the second operational clock CLK2 to the second connecting section 30. In this way, the phase of the second operational clock CLK2 is shifted relative to the phase of the first operational clock CLK1. The phase difference between the first operational clock CLK1 and the second operational clock CLK2 is preferably 180′. In this way, the clock output section 36 outputs the first operational clock CLK1 and the second operational clock CL2 with phases that are the inverse of each other to the first connecting section 28 and the second connecting section 30.

Even if one of the first memory card 90 and second memory card 92 is not connected to the first connecting section 28 or the second connecting section 30, when the other of the first memory card 90 and second memory card 92 is connected, the clock output section 36 outputs both of the first operational clock CLK1 and the second operational clock CLK2 with phases that are the inverse of each other to the first connecting section 28 and the second connecting section 30. When one of the memory cards (e.g. the second memory card 92) is newly connected to one of the connecting sections (e.g. the second connecting section 30), the clock output section 36 stops the output of the operational clock (e.g. the second operational clock CLK2) to the newly connected connecting section (e.g. the second connecting section 30). In this state, the command input/output section 34 performs the initial setting for the newly connected memory card (e.g. the second memory card 92). After the initial setting is completed, the clock output section 36 outputs the operational clock (e.g. the second operational clock CLK2) whose phase is shifted relative to the operational clock (e.g. the first operational clock CLK1) that continues to be output, to the connecting section (e.g. the second connecting section 30) for which the operational clock output is currently stopped. Furthermore, when the first memory card 90 or the second memory card 92 is separated from the first connecting section 28 or the second connecting section 30, the clock output section 36 continues the output of the first operational clock CLK1 or the second operational clock CLK2 to the first connecting section 28 or second connecting section 30 from which the first memory card 90 or second memory card 92 was disconnected, without interruption.

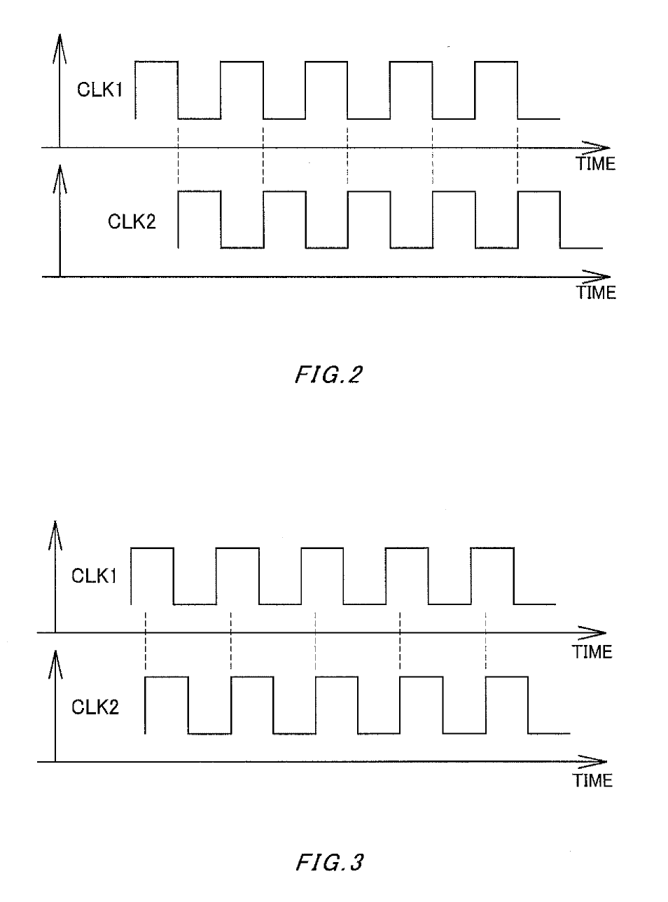

FIG. 2 shows operational clocks input to the first connecting section and the second connecting section. As shown in FIG. 2, the operational clock CLK2 input to the second connecting section 30 from the clock output section 36 is phase-shifted by 180° relative to the operational clock CLK1 input to the first connecting section 28 from the clock output section 36. In this way, the clock output section 36 outputs the operational clocks CLK1 and CLK2 having inverse phases to the first connecting section 28 and the second connecting section 30, respectively. Therefore, the rising of the first operational clock CLK1 occurs at substantially the same time as the falling of the second clock CLK2. As a result, the electromagnetic waves caused by the rising of the first operational clock CLK1 and the electromagnetic waves caused by the falling of the second operational clock CLK2 have inverse phases, and therefore these two types of electromagnetic waves cancel each other out. As a result, the emission characteristic is improved.

FIG. 3 shows another example of operational clocks input to the first connecting section and the second connecting section. As shown in FIG. 3, the first operational clock CLK1 input to the first connecting section 28 and the second operational clock CLK2 input to the second connecting section 30 are phase-shifted relative to each other. The phase shift is greater than 0° and less than 180°. As a result, the rising times of the two operational clocks CLK1 and CLK2 are temporally shifted, and therefore the overlap between the electromagnetic waves caused by the rising of the first operational clock CLK1 and the electromagnetic waves caused by the rising of the second operational clock CLK2 is restricted, thereby decreasing the effect of noise caused by electromagnetic waves on the surrounding area.

The following describes the operation of the image capturing apparatus 10 described above. First, when a user presses a release button of the input section 24 while viewing an image displayed in the display section 18, various settings are performed based on the information detected by the photometric sensor 20 and the focal point detection sensor 22. After this, the image capturing element 14 receives the light of the subject image, photoelectrically converts the received light, and outputs an image signal to the image processing section 16. The image processing section 16 converts the image signal into image data. After this, the image data is input to the memory cards 90 and 92 through the ASIC 26 as storage information, which is described below, either in response to a manipulation of the input section 24 by the user or automatically. Furthermore, as a result of a manipulation of the input section 24 by the user, the storage information stored in the memory cards 90 and 92 is acquired and displayed in the display section 18 as an image.

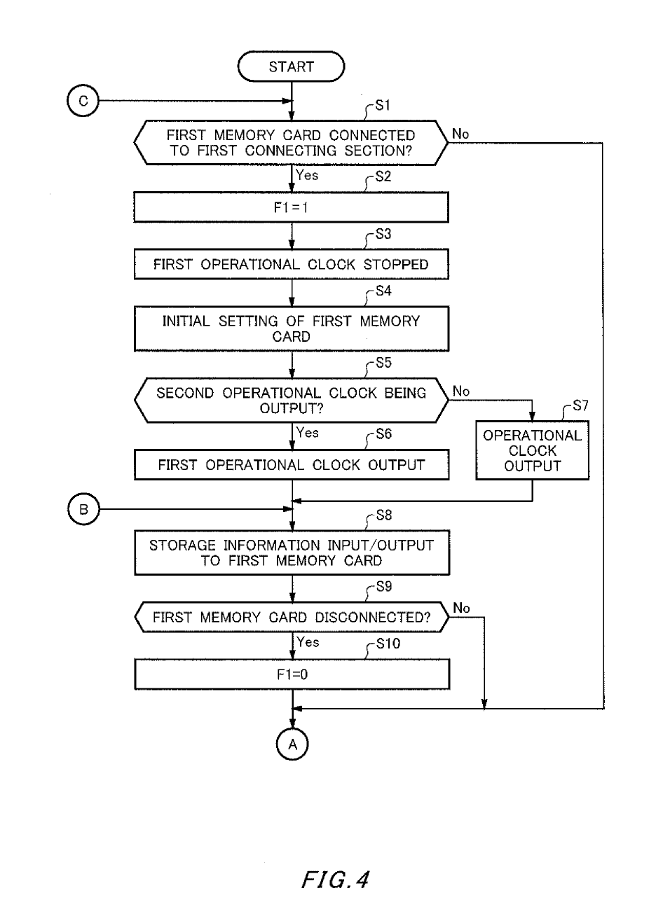

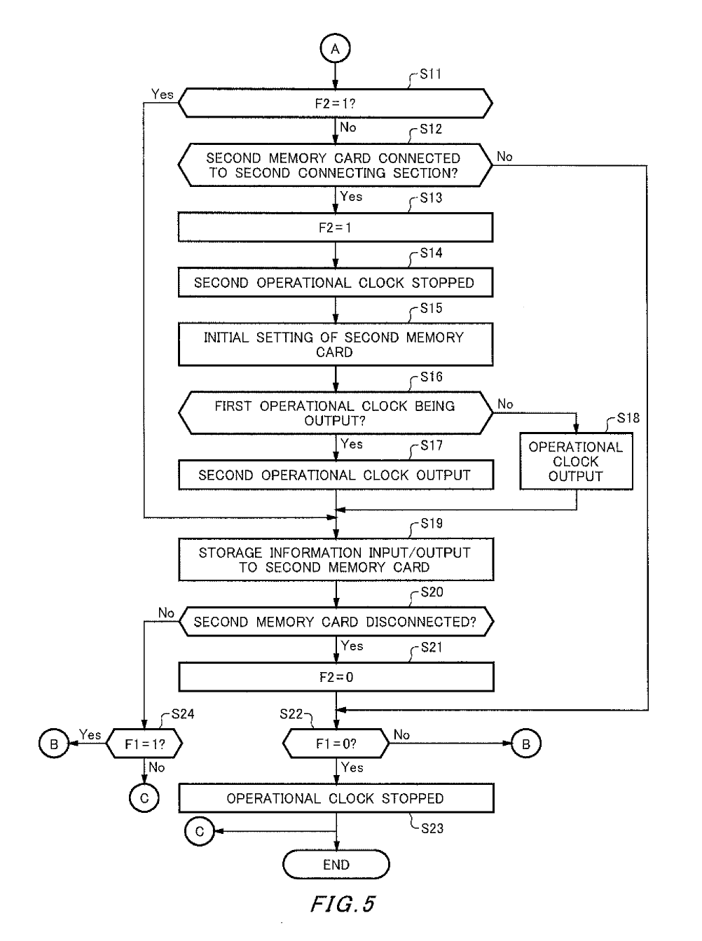

FIG. 4 is a flowchart describing the first half of the storage information input/output operation performed by the image capturing apparatus. FIG. 5 is a flowchart describing the second half of the storage information input/output operation performed by the image capturing apparatus.

When the power supply is turned ON, a program is executed based on the flowcharts of FIGS. 4 and 5. When this flow is started, a flag F 1 and a flag F2, which are described further below, are both set to 0. The command input/output section 34 of the ASIC 26 determines whether the first memory card 90 is connected to the first connecting section 28 (S1). When the command input/output section 34 determines that the first memory card 90 is not connected (S1: No), the process of step S11 described below is performed.

When the command input/output section 34 determines that the first memory card 90 is connected (S1: Yes), the command input/output section 34 sets the flag F1 to 1 (S2). The flag F1 is set to 1 when connection of the first memory card 90 is detected, and is set to 0 when connection of the first memory card 90 is not detected. Next, the clock output section 36 stops the output of the first operational clock CLK1 to the first connecting section 28 (S3). If the first operational clock CLK1 is not being output, this state is maintained. After this, the command input/output section 34 performs initial setting of the first memory card 90 (S4). This initial setting includes acquiring the storage rate and acquisition rate of the first memory card 90 for storage information, detecting the available space, and the like.

Next, the command input/output section 34 determines whether the second operational clock CLK2 is being output to the second connecting section 30 by the clock output section 36 (S5). When it is determined that the second operational clock CLK2 is being output (55: Yes), the clock output section 36 outputs the first operational clock CLK1, which is currently stopped, to the first connecting section 28 (S6). Here, the clock output section 36 shifts the phase of the first operational clock CLK1 relative to the phase of the second operational clock CLK2 being output, and outputs the phase-shifted first operational clock CLK1. In this way, the clock output section 36 outputs to the first connecting section 28 the first operational clock CLK1 that is phase-shifted relative to the second operational clock CLK2 being output to the second connecting section 30. On the other hand, when it is determined that the second operational clock CLK2 is not being output (S5: No), the clock output section 36 outputs both the first operational clock CLK1 and the second operational clock CLK2 (S7). Since the second operational clock CLK2 is output through the delay circuitry section 40 of the clock output section 36, the phase of the second operational clock CLK2 is shifted relative to the first operational clock CLK1 that is directly output from the generating section 38 without passing through the delay circuitry section 40. This phase shift is preferably 180°, thereby causing the phases to be the inverse of each other, as shown in FIG. 2.

Next, the data input/output section 32 performs input and output of storage information to and from the first memory card 90, according to instructions from the CPU 12 (S 8). While the storage information is being input and output to and from the first memory card 90, the clock output section 36 continues the output of the second operational clock CLK2 to the second connecting section 30, without performing input or output of storage information.

After this, the command input/output section 34 determines whether the first memory card 90 is disconnected from the first connecting section 28 (S9). When it is determined that the first memory card is disconnected from the first connecting section 28 (S9: Yes), the command input/output section 34 sets the flag F1 to 0 (S10). Even when the first memory card 90 is disconnected from the first connecting section 28, the clock output section 36 continues outputting the first operational clock CLK1 to the first connecting section 28. After the process of step S10, when the command input/output section 34 detei nines that the first memory card 90 is disconnected from the first connecting section 28 (S9: No), the process of step S11 shown in FIG. 5 is performed, as shown by A in FIGS. 4 and 5.

The command input/output section 34 determines whether the flag F2 is set to 1 (S11). The flag F2 is set to 1 when connection of the second memory card 92 is connected, and is set to 0 when connection of the second memory card 92 is not connected. When the command input/output section 34 determines that the flag F2 is set to 1 (S11: Yes), the process of step S19 described further below is performed. On the other hand, when the command input/output section 34 determines that the flag F2 is set to 0 (S11: No), the command input/output section 34 determines whether the second memory card 92 is connected to the second connecting section 30 (S12).

Next, when the command input/output section 34 determines that the second memory card 92 is not connected, the command input/output section 34 (S12: No), the process of step S22 described further below is performed. On the other hand, when the command input/output section 34 determines that the second memory card 92 is connected (S12: Yes), the flag F2 is set to 1 (S13). The clock output section 36 stops the second operational clock CLK2 (S14). If the second operational clock CLK is not being output, this state is maintained. The command input/output section 34 performs initial setting of the second memory card 92 (S15). Next, the clock output section 36 determines whether the first operational clock CLK1 is being output (S16). When it is determined that the first operational clock CLK1 is being output, the clock output section 36 outputs the second operational clock CLK2, which is currently stopped, to the second connecting section 30 (S17). Here, the clock output section 36 outputs the second operational clock CLK2 through the delay circuitry section 40. Therefore, the phase of the second operational clock CLK2 is shifted relative to the phase of the first operational clock CLK1, which is currently stopped, and output. In this way, the clock output section 36 outputs to the second connecting section 30 the second operational clock CLK2 that is phase-shifted relative to the first operational clock CLK1 being output to the first connecting section 28. On the other hand, when it is determined that the first operational clock CLK1 is not being output (S16: No), the clock output section 36 outputs the second operational clock CLK2 and the first operational clock CLK1, which is currently stopped. Since the second operational clock CLK2 is output through the delay circuitry section 40 of the clock output section 36, the phase of the second operational clock CLK2 is shifted relative to the first operational clock CLK1 that is directly output from the generating section 38 without passing through the delay circuitry section 40.

Next, the data input/output section 32 performs input and output of storage information to and from the second memory card 92, according to instructions from the CPU 12 (S19). If the command input/output section 34 has determined that F2=1 at step S11, the process of step S19 is performed and the processes of steps S12 to S17 are not performed. In this way, when the connected state of the second memory card 92 is maintained, the storage information is input and output to and from the second memory card 92 by the data input/output section 32 without the initial setting of the second memory card 92 being performed. While the storage information is being input and output to and from the second memory card 92, the clock output section 36 continues the output of the first operational clock CLK1 to the first connecting section 28.

After this, the command input/output section 34 determines whether the second memory card 92 is disconnected from the second connecting section 30 (S20). When it is determined that the second memory card 92 is disconnected (S20: Yes), the command input/output section 34 sets the flag F2 to 0 (S21). Even when the second memory card 92 is disconnected, the clock output section 36 continues outputting the second operational clock CLK2 to the second connecting section 30.

The command input/output section 34 determines whether the flag F1 is set to 0 (S22). When the command input/output section 34 determines that the flag F1 is set to 0 (S22: Yes), the process of step S23 is performed. This state means that the flag F1 and the flag F2 are both 0. Next, the clock output section 36 stops the output of the first operational clock CLK1 and the second operational clock CLK2 (S23). After this, the flow returns to the process of step S1, as shown by C in FIGS. 4 and 5.

On the other hand, when it is determined at step S20 that the second memory card 92 is not disconnected (S20: No), the command input/output section 34 determines whether the flag F 1 is set to 1 (S24). When it is determined that the flag F1 is set to 0 (S24: No), the command input/output section 34 returns to the process of step S1 described above, as shown by C in FIGS. 4 and 5.

On the other hand, when it is determined at step S24 that the flag F1 is set to 1 (S24: Yes), the command input/output section 34 performs the process of step S8, as shown by B in FIGS. 4 and 5. When it is determined at step S22 that the flag F1 is set to 1 (S22: No), the command input/output section 34 performs the process of step S8, as shown by B in FIGS. 4 and 5. In this way, when connection of the first memory card 90 is already detected and the flag F1 is set to 1, the process of step S8 is performed and the processes of steps S1 to S6 are not performed. As a result, the data input/output section 32 inputs and outputs the storage info nation to and from the first memory card 90 without performing the initial setting of the first memory card 90. The reason that there is no need to perform the initial setting is that the output of the first operational clock is continued. After this, the flow charts of FIGS. 4 and 5 are repeated until the power supply is turned OFF.

As described above, in the image capturing apparatus 10, the clock output section 36 shifts the phases of the first operational clock CLK1 output to the first connecting section 28 and the second operational clock CLK2 output to the second connecting section 30 relative to each other. In this way, a portion of the electromagnetic waves caused by the rising and falling of the first operational clock CLK1 cancel out a portion of the electromagnetic waves caused by the rising and falling of the second operational clock CLK2. Therefore, the effect of noise caused by the electromagnetic waves of the operational clocks CLK1 and CLK2 on the surrounding area can be decreased, thereby improving the characteristics such as EMC (ElectroMagnetic Compatibility).

Furthermore, in the image capturing apparatus 10, the clock output section 36 can cause more of the electromagnetic waves caused by the first operational clock CLK1 and the electromagnetic waves caused by the second operational clock CLK2 to cancel each other out, by shifting the phase of the first operational clock CLK1 and the phase of the second operational clock by 180° relative to each other, thereby creating inverse phases. As a result, the effect of electromagnetic waves on the surrounding area is further decreased.

In the image capturing apparatus 10, the operational clocks CLK1 and CLK2 are also output to the first connecting section 28 and second connecting section 30 when storage information is not being stored in or acquired from the memory cards 90 and 92. Therefore, even when resuming storage or acquisition of the storage information to or from the memory cards 90 and 92, there is no need to perform the initial setting. As a result, the time necessary for storing and acquiring the storage information can be decreased, while also decreasing the effect of the electromagnetic waves described above.

In the image capturing apparatus 10, by shifting the phase of the first operational clock CLK1 and the phase of the second operational clock CLK2 to be 180° from each other, the amount of current flowing simultaneously can be decreased relative to a case in which two clocks with the same phase are output. As a result, the image capturing apparatus 10 can reduce power consumption.

The above embodiment describes an example in which the first connecting section 28 and second connecting section 30 are connected to the two memory cards 90 and 92, which are the external devices, but the number of connecting sections is not limited to two. For example, with n representing a positive integer, an embodiment may be realized in which the electronic device includes 2n connecting sections, i.e. an even number of connecting sections. In this case, first operational clocks that all have the same phase may be output to n connecting sections, and second operational clocks having phases differing from the phase of the first operational clocks may be output to the other n connecting sections. The phase shift between the phase of the first operational clocks and the phase of the second operational clocks is preferably 180°, such that the phases are inverses of each other.

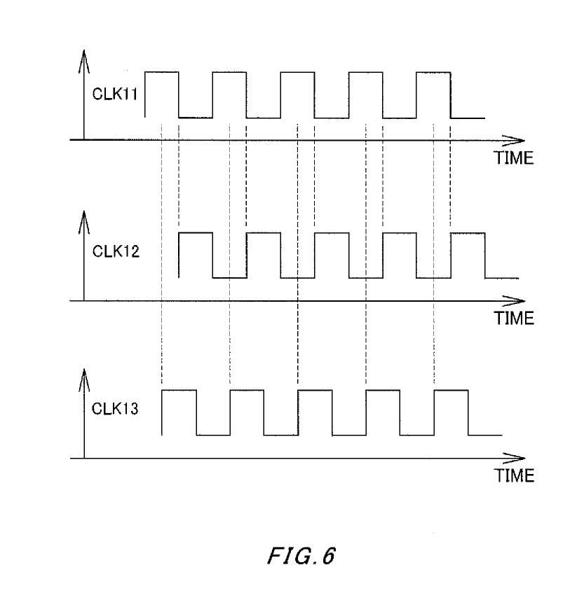

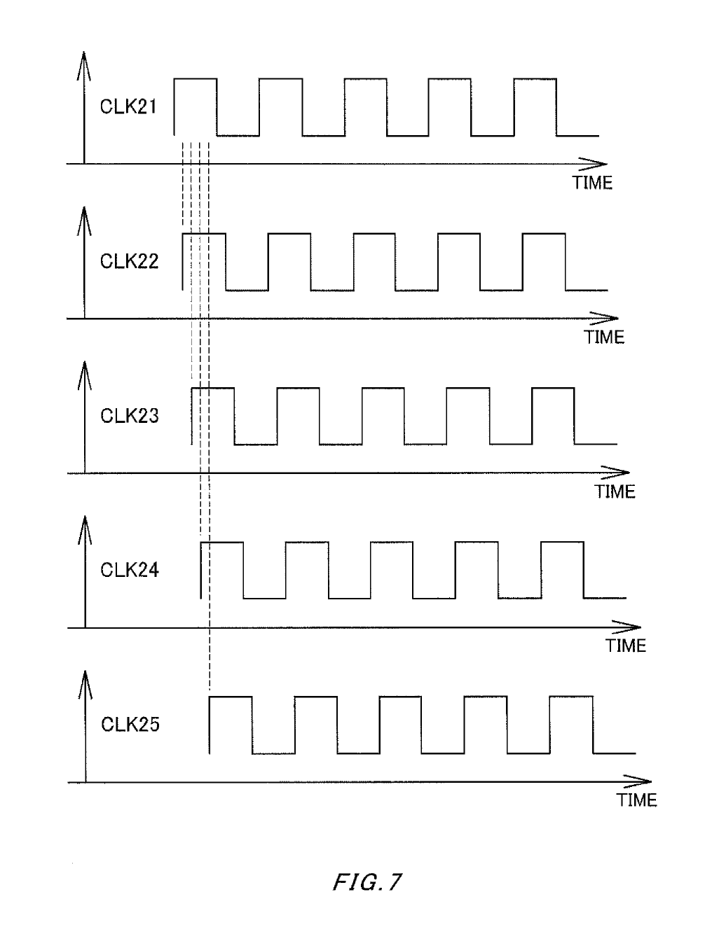

The following describes an electronic device including 2n+1, i.e. an odd number, of connecting sections, with reference to the drawings. For ease of explanation, an example in which operational clocks are output to five connecting sections is described. FIG. 6 shows operational clocks output to five connection sections. FIG. 7 shows other operational clocks output to five connecting sections.

As shown in FIG. 6, first operational clocks CLK11 are output to two of the connecting sections. Second operational clocks CLK12, which have phases differing by 180° from the phase of the first operational clocks CLK11, are output to another two of the connecting sections. A third operational clock 13 whose phase differs from both the phase of the second operational clocks CLK12 and the first operational clocks CLK11 is output to the remaining connecting section. The third operational clock CLK13 preferably has a phase that is shifted by 90° relative to both the phase of the second operational clocks CLK12 and the first operational clocks CLK11. In the same manner, when outputting operational clocks to 2n+1 connecting sections in a case where n is two or more, the first operational clock CLK11 may be output to n connecting sections, the second operational clock CLK12 may be output to another n of the connecting sections, and the third operational clock CLK13 may be output to the remaining one connecting section.

As an example of outputting different operational clocks to five connecting section, operational clocks CLK21, CLK22, CLK23, CLK24, and CLK25, which each have a different phase, may be output to the five connecting sections, as shown in FIG. 7. In this case, the phase difference between each clock is preferably (180/5)°. In the same manner, when outputting operational clocks to 2n+1 connecting sections in a case where n is two or more, the phase difference between each operational clock may be (180/n)°.

In the above embodiment, a memory card is described as an example of an external device, but the external device is not limited to this. The external device may be two liquid crystal displays connected to one computer, for example. Furthermore, the external devices may be different types of devices that are supplied with the same operational clocks. Foe example, the external devices can be different memory cards that are supplied with the same operational clocks. The device to which different memory cards are connected may be a card slot, for example.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. An electronic device comprising:
a plurality of connecting sections that are respectively connected to a plurality of external devices having the same frequencies for operational clocks used to communicate signals; and
a clock output section that outputs, respectively to the connecting sections, operational clocks that are phase-shifted relative to each other.

2. The electronic device according to claim 1, wherein
the clock output section outputs operational clocks with inverse phases to two of the connecting sections.

3. The electronic device according to claim 1, wherein
when an external device is connected to one of the connecting sections and no external device is connected to another connecting section, the clock output section outputs operational clocks that are phase-shifted relative to each other to the one connecting section and the other connecting section.

4. The electronic device according to claim 3, wherein
when an external device is connected to the other connecting section, the clock output section stops output of the operational clock to the other connecting section and, after an initial setting of the external device is completed, outputs to the other connecting section an operational clock that is phase-shifted with reference to the operational clock output to the one connecting section.

5. The electronic device according to claim 4, wherein
when the external device is disconnected from the other connecting section, the clock output section continues outputting the operational clock to the other connecting section.

6. The electronic device according to claim 1, wherein
the clock output section includes a delay circuitry section that delays an operational clock.

7. The electronic device according to claim 1, wherein
each of the connecting sections is connected to a memory card serving as an external device.
